(19) United States
(12) Patent Application Publication
(10) Pub. No.: US 2009/0129003 A1
(43) Pub. Date: May 21, 2009

(54) Operator control unit

(76) Inventors: Kurt Bruck, Providence, RI (US); Hoi Tong, Newton, MA (US); Geoffrey B. Lansberry, Andover, MA (US); Jake Warren, Milford, MA (US); Alex Kirilov, Littleton, MA (US)

Correspondence Address: David W. Poirier;IANDIORIO TESKA & COLEMAN, INTELLECTUAL PROPERTY LAW ATTORNEYS, 260 BEAR HILL ROAD, WALTHAM, MA, 02451-1018, US

(21) Appl. No.: 12/284,307

(22) Filed: Sep. 19, 2008

Related U.S. Application Data
(60) Provisional application No. 60/994,414, filed on Sep. 19, 2007.

(51) Int. Cl. H05K 7/10; H04Q 9/00

(52) U.S. Cl. 361/679.4; 318/16

(57) ABSTRACT

A mobile operator control unit for remotely controlling a robot includes a housing with a reconfigurable user interface with multiple sockets. A plurality of control modules are each removably received in a socket and include one or more switches. A module interface is connected to the one or more switches. A baseboard processing unit is connected to each module interface for receiving and processing signals received from the module interfaces. A transmitter is responsive to the baseboard processing unit for transmitting signals to the robot based on the activation of the module switches.

### RELATED APPLICATIONS

This application claims benefit of and priority to U.S. Patent Application Ser. No. 60/994,414 filed Sep. 19, 2007, which is herein incorporated into this application by reference.

### FIELD OF THE INVENTION

This invention relates to mobile operator controlled units for remotely controlling robots.

### BACKGROUND OF THE INVENTION

There are a variety of mobile remotely controlled robots useful in carrying out a number of functions. The applicants' “Talon” robot, for example, includes a robot arm with an end effector and numerous cameras. The operator control unit for the Talon robot includes joysticks for driving the robot and for manipulating the robot arm and the end effector gripper jaws as well as other robot control switches. The control unit also has a monitor for viewing the output of the various robot cameras. The applicants' “Swords” robot includes a weapon and the operator control unit for that robot includes various switches for activating and firing the weapon.

Most robot operator control units are configured specially for one specific robotic platform. When the robot platform changes slightly, typically so too must the operator control unit. For example, suppose one robot platform includes a main arm with only one degree of freedom. That robot's operator control unit will generally not adequately control a robot platform with an arm having two or more degrees of freedom. Or, suppose new sensors (e.g., a biological or chemical sensor) and/or subassemblies or cameras are added to a particular robot platform. That robot's operator control unit, then, would have to be reengineered to accommodate the added equipment.

It would therefore be beneficial if an operator control unit were easily reconfigurable. No such operator control unit is known. Also, many operator control units (and robots) are used by the military, police and swat teams. The operator control unit, therefore, is preferably water resistant, light weight, shock resistant, and easy to use. If an operator control unit is damaged, or is faulty, or wears out, it would be desirable to easily replace it or its subcomponents in the field.

### BRIEF SUMMARY OF THE INVENTION

It is therefore an object of this invention to provide and easily reconfigurable operator control unit for a robot.

It is a further object of this invention to provide such an operator control unit which is more easily repaired.

It is a further object of this invention to provide such an operator control unit which meets military requirements.

The invention results from the realization that an easily reconfigurable operator control unit includes multiple sockets which receive different robot control modules so that when the robot is reconfigured, the same operator control unit can be used.

The subject invention, however, in other embodiments, need not achieve all these objectives and the claims hereof should not be limited to structures or methods capable of achieving these objectives.

This invention features, in one example, a mobile operator control unit for remotely controlling a robot. The control unit includes a housing with a reconfigurable user interface including multiple sockets, a plurality of control modules each removably received in a socket and including one or more switches, and a module interface connected to the one or more switches. A baseboard processing unit is connected to each module interface for receiving and processing signals received from the module interfaces. A transmitter is responsive to the baseboard processing unit for transmitting signals to the robot based on the activation of the module switches.

In one embodiment, each module interface may be configured to convert signals received by the switches to a common format. The format may be compatible with a USB connection between each module interface and the baseboard processing unit. The switches may include dials, joysticks, buttons, and/or selection switches. Each control module may include a plate housing the switches, a circuit board support depending downward from a rear face of the plate into a socket, and the module interface is configured as a circuit board supported by the support and including connectors for wires extending between the switches and the circuit board. The plate may be removably and sealingly engaged over a socket. The housing may further include a monitor. The transmitter may be housed in a robot communications pack removably attached to the housing. A lid may be hinged to a base and the panel is the top surface of the base. The lid may include a monitor. The transmitter may be housed in a robot communications pack removably attached to the back of the lid.

The subject invention also features a mobile operator control unit for remotely controlling a robot, the control unit including a housing with a reconfigurable user interface including multiple sockets, each socket configured to removably receive one of a plurality of control modules for configuring the control mechanisms of the control unit, a common interface connected to each socket, a baseboard processing unit connected to the socket interface for receiving and processing signals received from the module interfaces, and a transmitter responsive to the baseboard processing unit for transmitting signals to one or more robots based on the activation of the module switches.

In one embodiment, the operator control may further include the plurality of control modules in which each control module includes one or more switches and a module interface connectable to the common interface. The housing may further include a monitor. A lid may be hinged to a base and the panel is the top surface of the base. The lid may include a monitor.

This invention also features a mobile operator control unit for remotely controlling a robot, the control unit including a housing with a reconfigurable user interface including a plurality of control modules each removably received in the control unit and including one or more switches, a processor having code executable thereon, the code including a user input manager responsive to the switches for interpreting the function of the switches and monitoring the user interface for changes in the user interface, a robot controller manager responsive to the user input manager for monitoring data relating to operating the robot, a robot communications manager responsive to the robot controller manager for communicating signals to the robot based on the activation of the module switches, a display manager for controlling the display of information, and a status manager for indicating the status of the robot.

In another embodiment, the robot controller manager may include a driving manager responsive to the user input manager for monitoring data relating to driving the robot, and an arm manager responsive to the user input manager for monitoring data relating to operating an arm of the robot.

This invention further features a method for providing a mobile robot operator control unit to remotely control a robot, the method comprising the steps of providing a housing with a reconfigurable user interface including multiple sockets, providing a plurality of control modules each including: one or more switches, and a module interface connected to the one or more switches, installing the plurality of control modules in the corresponding sockets to provide an initial configuration of the control mechanisms of the control unit, receiving and processing signals received from the module interfaces, and transmitting signals to the robot based on the activation of the module switches.

In one embodiment, the method may further include the steps of removing one or more of the plurality of control modules from their corresponding sockets, and installing one or more different control modules to reconfigure the initial configuration of the control mechanisms of the control unit.

### BRIEF DESCRIPTION OF THE SEVERAL VIEWS OF THE DRAWINGS

Other objects, features and advantages will occur to those skilled in the art from the following description of a preferred embodiment and the accompanying drawings, in which:

FIG. 1 is a schematic three dimensional view showing one specific robot platform;

FIG. 2 is a schematic three dimensional view showing a prior art operator control unit for the robot shown in FIG. 1;

FIG. 3 is a schematic three dimensional front view of an example of an operator control unit in accordance with the subject invention;

FIG. 4 is a schematic three dimensional rear view of the operator control unit shown in FIG. 3;

FIG. 5 is a schematic block diagram showing the connections between the individual robot control modules and the baseboard processing unit in accordance with one example of an operator control unit of the subject invention;

FIG. 6 is a schematic three dimensional top view of the operator control unit shown in FIGS. 3 and 4;

FIG. 7 is another schematic three dimensional front view showing the operator control unit of FIG. 4;

FIG. 8 is a schematic three dimensional front view showing in more detail the monitor assembly of the operator control unit shown in FIG. 3;

FIG. 9 is a schematic three dimensional rear view of the monitor assembly shown in FIG. 8;

FIG. 10 is a schematic three dimensional view of a communications interface for the operator control unit of FIG. 3;

FIG. 11 is a schematic block diagram showing the primary components associated with the communications interface of the central processing unit of FIG. 10;

FIG. 12 is a schematic block diagram showing the primary operating system components associated with the operator control unit of FIG. 3;

FIG. 13 is a schematic three dimensional top view showing an example of a robot control module of the operator control unit of FIG. 3;

FIG. 14 is a schematic three dimensional rear view of the robot control module of FIG. 13;

FIG. 15 is a schematic three dimensional top view again showing an example of a robot control module the operator control unit of FIG. 3;

FIG. 16 is a schematic three dimensional view showing the underside of the robot control module of FIG. 15;

FIG. 17 is a schematic three dimensional front view showing an example of a robot control module switch in accordance with the subject invention;

FIG. 18 is a schematic three dimensional view showing another example of a robot control module switch in accordance with the subject invention;

FIG. 19 is a schematic three dimensional front view showing an example of a robot control module joystick switch;

FIG. 20 is a schematic three dimensional front view showing an example of a robot control module dial switch;

FIG. 21 is a schematic exploded three dimensional top view showing another example of a robot control module and a housing panel socket in accordance with the subject invention;

FIG. 22 is schematic three dimensional front view showing another example of an operator control unit in accordance with the subject invention.

FIG. 23 is a schematic three dimensional view showing another example of an operator control unit in accordance with the subject invention;

FIG. 24 is a block diagram showing the primary components of the architecture of the software associated with the operator control unit in accordance with one example of the subject invention;

FIG. 25 is a schematic block diagram showing the robot controller manager of FIG. 24

FIG. 26 is a schematic block diagram showing the driving user input manager in one example of the user input manager of FIG. 24;

FIG. 27 is a schematic block diagram showing the robot communication manager of FIG. 24; and

FIG. 28 is a flow chart depicting the steps of a method according to an embodiment of the subject invention.

### DETAILED DESCRIPTION OF THE INVENTION

Aside from the preferred embodiment or embodiments disclosed below, this invention is capable of other embodiments and of being practiced or being carried out in various ways. Thus, it is to be understood that the invention is not limited in its application to the details of construction and the arrangements of components set forth in the following description or illustrated in the drawings. If only one embodiment is described herein, the claims hereof are not to be limited to that embodiment. Moreover, the claims hereof are not to be read restrictively unless there is clear and convincing evidence manifesting a certain exclusion, restriction, or disclaimer.

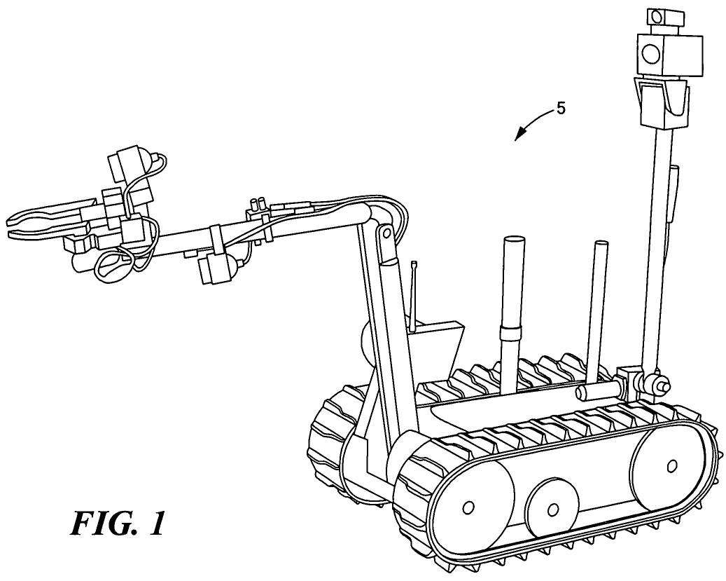

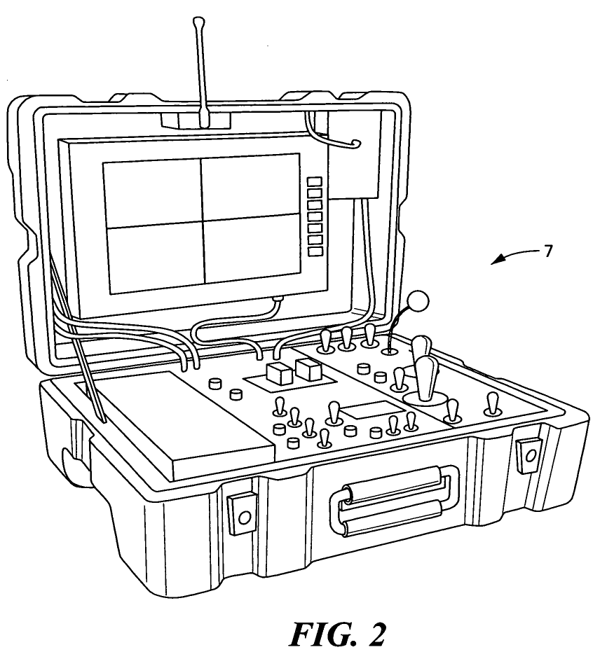

As described above, most robot operator control units are configured specially for one specific robot platform. When the robot platform changes slightly, typically so too must the operator control unit. For example, FIGS. 1 and 2 respectively show the applicants' prior art Talon robot 5 and the prior art operator control unit 7 for the robot. This prior art operator control unit does not easily accommodate the addition of new controls, sensors, or the like. If an upgrade to the existing fielded robot requires new operator controls, the customer may need an entirely different control unit to effectively control the robot.

In contrast, the operator control unit of the subject invention implements a modular control scheme such that as the robots to be controlled evolves to include new features, new controls, such as joysticks, switches, potentiometers, feed-back, etc., may need to be added. Each module is intended to control a different feature on the robot, such as drive, arm, common settings, fire control, etc., with the modules easily removed, modified, customized, and swapped out by a field technician or user. If an upgrade to an existing fielded robot requires new operator controls, the upgrade can be shipped to the customer along with its new module. The customer could then install the upgrade and new module without requiring an entirely different control unit.

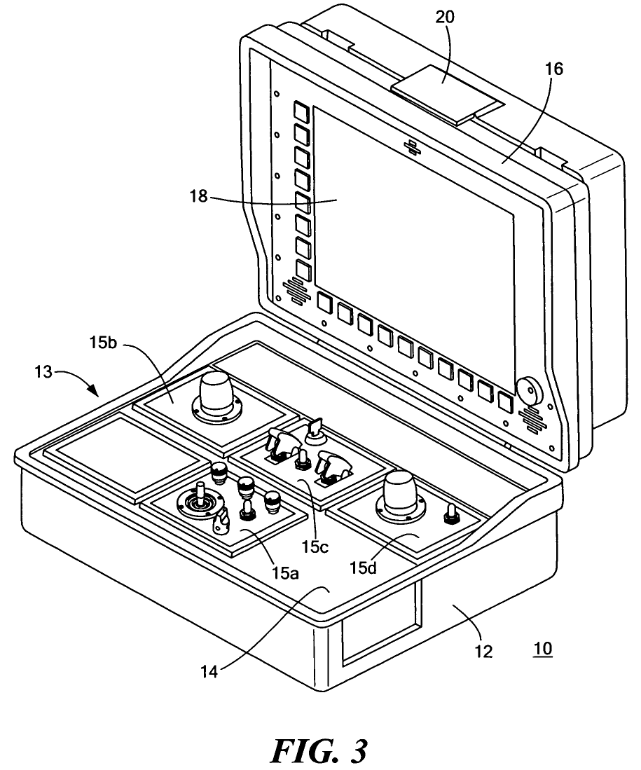

FIG. 3 shows an example of an operator control unit 10 in accordance with an example of the subject invention. Operator control unit 10 includes housing 12 having a reconfigurable user interface 13. User interface 13 includes a panel 14 having multiple sockets each configured to removably receive a select or desired control module 15a, 15b, 15c, and 15d. Control modules 15a-15d each include one or more switches 26 such as dials, joysticks, buttons, and/or selection switches. The preferred operator control unit 10 includes lid 16 hinged to base portion 12. Lid 16 includes monitor 18. A transceiver housed in a communications pack 20 removably attached to the back of operator control unit lid 16.

Operator control unit 10, FIG. 4, also includes an external USB port 22 for externally communicating with operator control unit 10. A heat sink 24 provides cooling for the electronic assemblies of operator control unit 10 and also provides access to the electronics when the heat sink is removed from the unit.

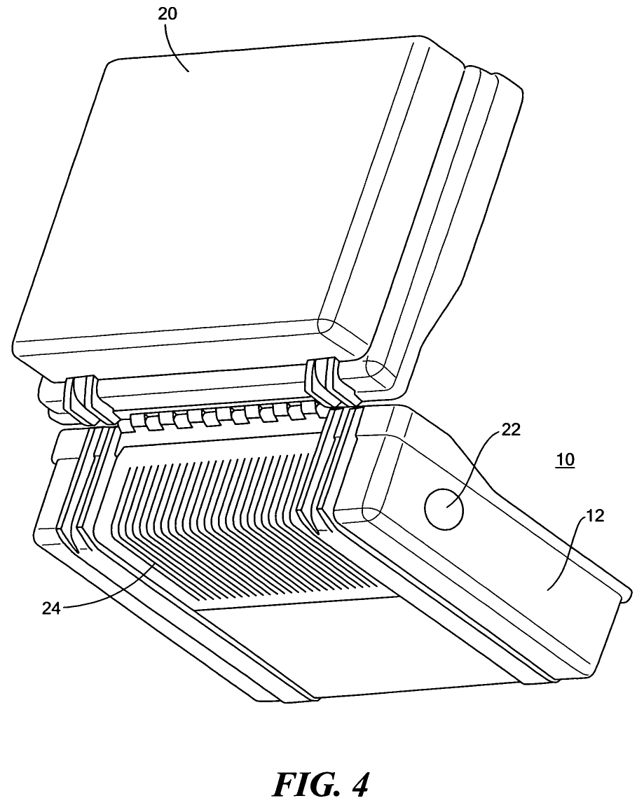

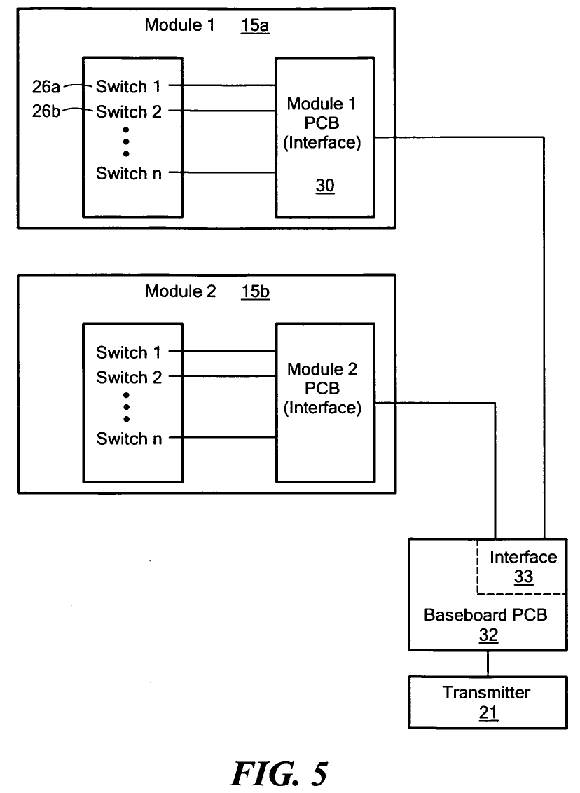

FIG. 5 shows how switches 26a, 26b, and the like of module 15a are connected to module printed circuit board interface 30 and how module printed circuit board interface 30 is connected to baseboard printed circuit board 32 within operator control unit housing portion 12, FIG. 3. Similarly, the switches of robot control module 15b, FIG. 5 are electrically connected to its interface module which, in turn, is connected via wiring to baseboard printed circuit board 32. Baseboard processing unit 32, FIG. 5 is electrically connected to each module interface for receiving and processing signals received from the switches via the module interfaces. Baseboard processing unit 32 may also include a common interface 33 connected to each socket for connection to each control module 15a-15d. Transmitter 21 (housed in communications pack 20, FIG. 4) is responsive to the baseboard processing unit for transmitting signals to the robot based on the activation of the module switches. In this way, operator control unit 10 can be easily reconfigured for different robot platforms by changing the control modules.

Each module interface 30 is configured to convert signals received by switches 26a, 26b of the module preferably to a common format. For example, there may be a USB connection between each module interface shown in FIG. 5 and baseboard processing unit 32.

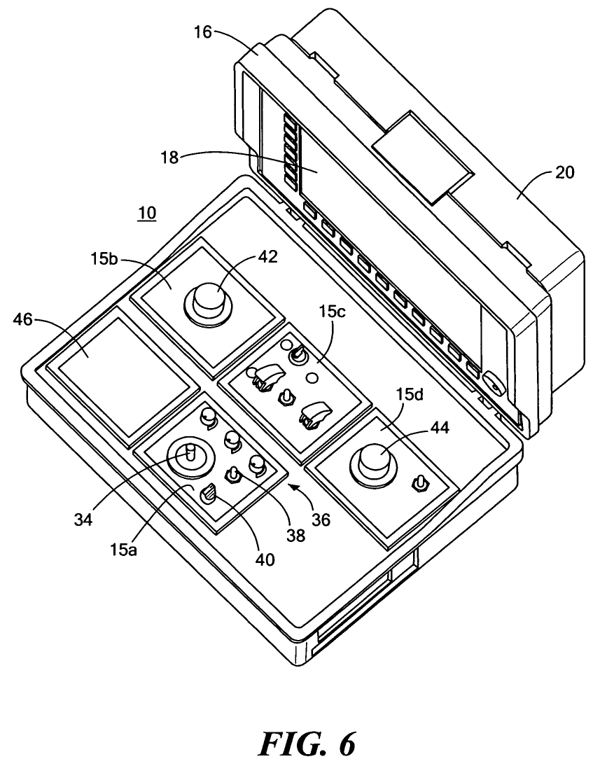

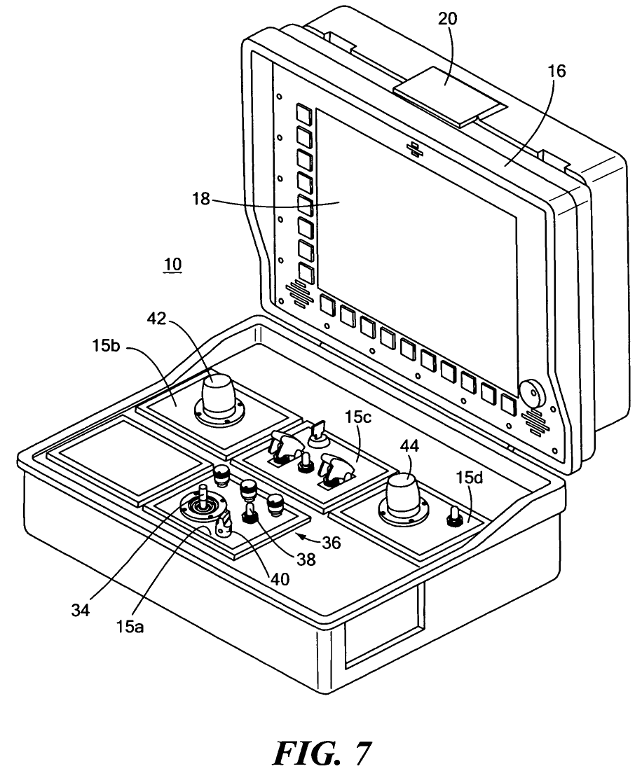

FIGS. 6 and 7 better illustrate several exemplary control modules 15a-15b of control unit 10. In this example, Module 15a controls the robot camera and speed control. Module 15a includes, for example, joystick 34 to control the pan and tilt of the camera and includes dials 36 to control functions such as the robot drive speed, turret speed and LED intensity. A button 38 is provided to allow the operator to talk through a speaker on the robot. A selection switch 40 provides selection of which robot camera the operator will view on display 18. Module 15b includes a dial 44 to adjust a turret control. Module 15c provides switches for fire control. Module 15c includes dial 42 for the drive control of the robot. A socket 46 provides space for an additional control module so that, in the future, if the robot's platform changes, an additional control module may be added to control unit 10 to update the functionality of the control unit without an operator having to replace the control unit with a new one.

The modules 15a, etc., preferably start as mass-produced “blanks” that have not been configured to a specific function. The blank includes the module housing, seals, and fastening hardware. Once a function has been decided upon for the module, a blank is machined to include the required hardware to meet its function. Six modules may be secured within the control unit's module grid arranged in two rows of three.

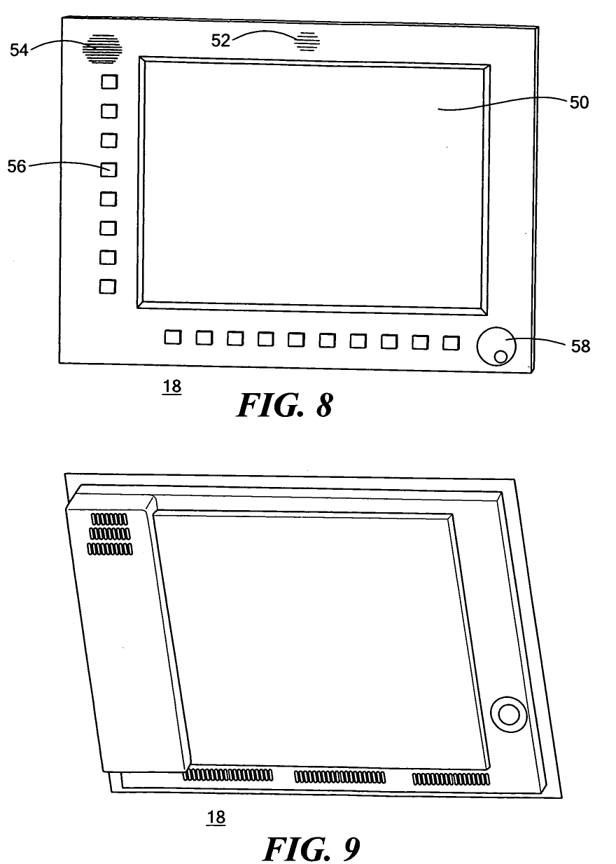

Monitor 18, FIGS. 8 and 9, includes display 50. Monitor 18 preferably also includes other components such as an integrated microphone 52, an integrated speaker 54, one or more buttons 56, and a function dial 58. Buttons 56 are preferably soft buttons so that an operator who is wearing gloves may easily push the buttons. Preferably, monitor 18 also includes a touch screen and is trans-reflective. Also, it is preferable that monitor 18 includes a Low-Voltage Differential Signaling (LVDS) input. Such a monitor can be obtained from the Comark Corporation of Medfield, Mass.

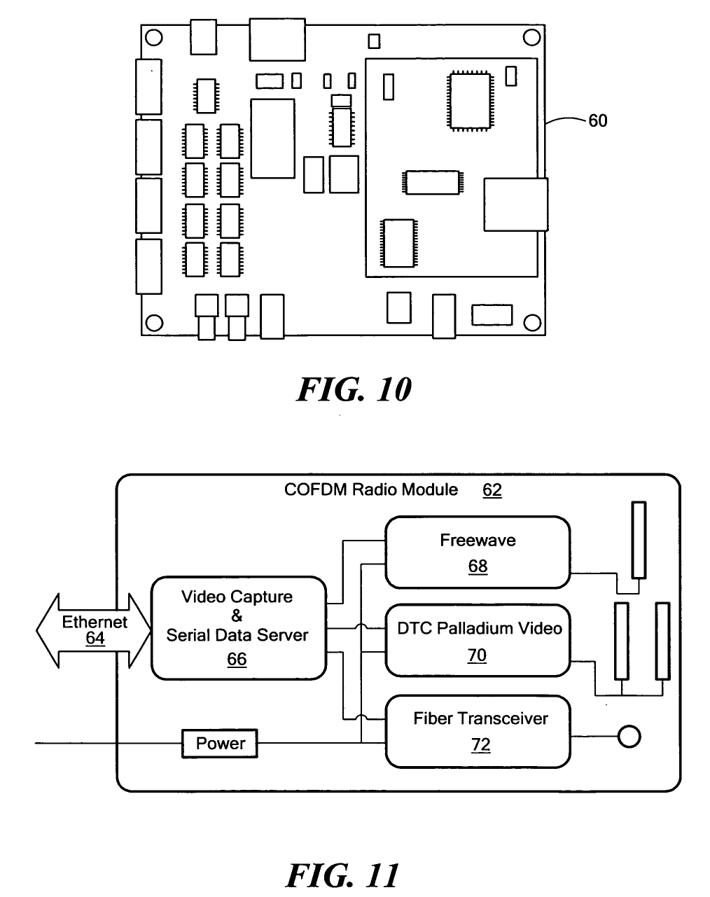

A communications interface 60, FIG. 10 shown also in block diagram 62, FIG. 11, provides radio communications with the robot. Interface 60 also provides an external user interface and allows the programming of communications interface 60. Interface 62 includes an Ethernet connection 64 to provide video capture and serial data communication 66. Interface 62 also includes one or more free wave ports 68 for transmitting data wirelessly to communicate with the robot. Video multiplexing is also provided through a DTC palladium video port 70 for transmitting through radio communications and a fiber transceiver port 72 for transmitting over fiber.

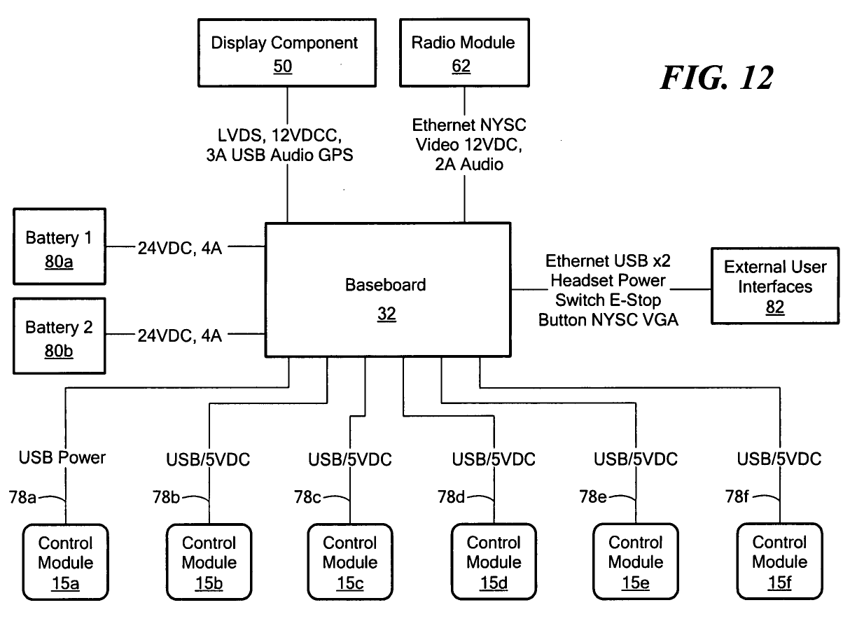

Baseboard processing unit 32, FIG. 12, is electrically connected to each of control modules 15a-15f through a USB connection on lines 78a-78f, respectively. Lines 78a-78f may also provide power, such as 5V DC to control modules 15a-15f. Baseboard processing unit is also connected to one or more batteries 80a, 80b that provide power, such as 12V DC at 4 amps, to baseboard processing unit 32. Processing unit 32 is also connected to monitor 50 and radio module 62. Baseboard processing unit 32 is preferably also connected to one or more external user interfaces 82 to provide video, sound, and data communication over an Ethernet connection and one or more USB connections.

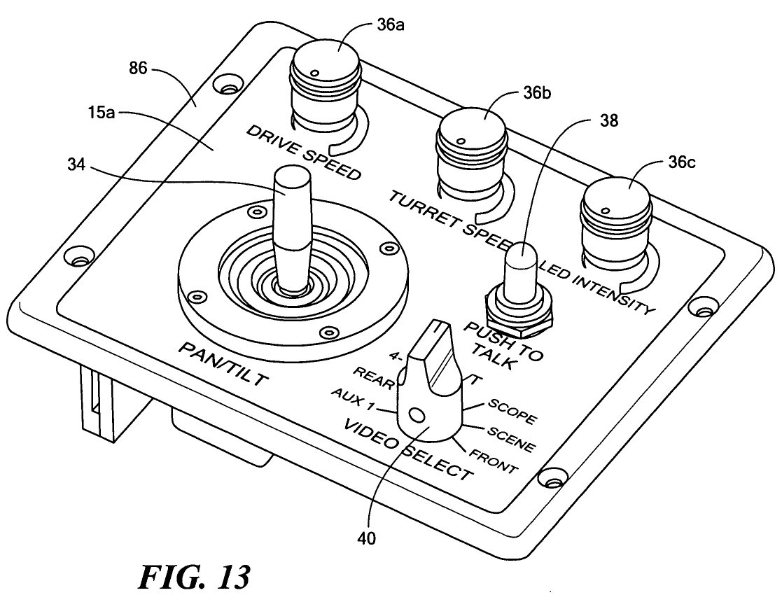

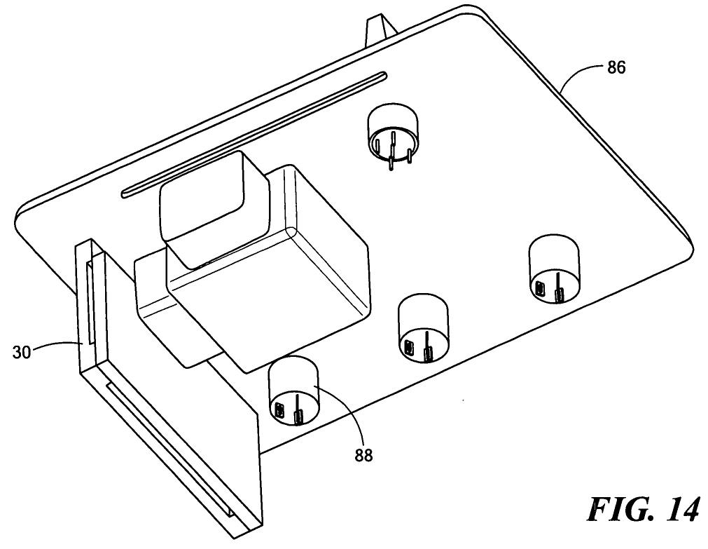

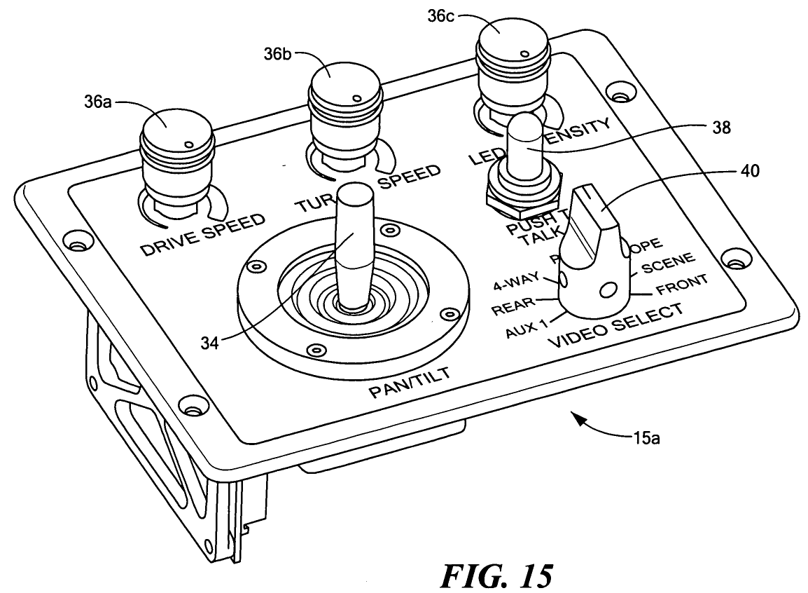

One specific control module 15a is shown in more detail in FIGS. 13-16. Dials 36a, 36b, and 36c are shown in addition to joystick 34, button 38, and selector switch 40. Typically, each control module includes a different set of switches which function to control a robot in some manner or to control some subsystem associated with the robot.

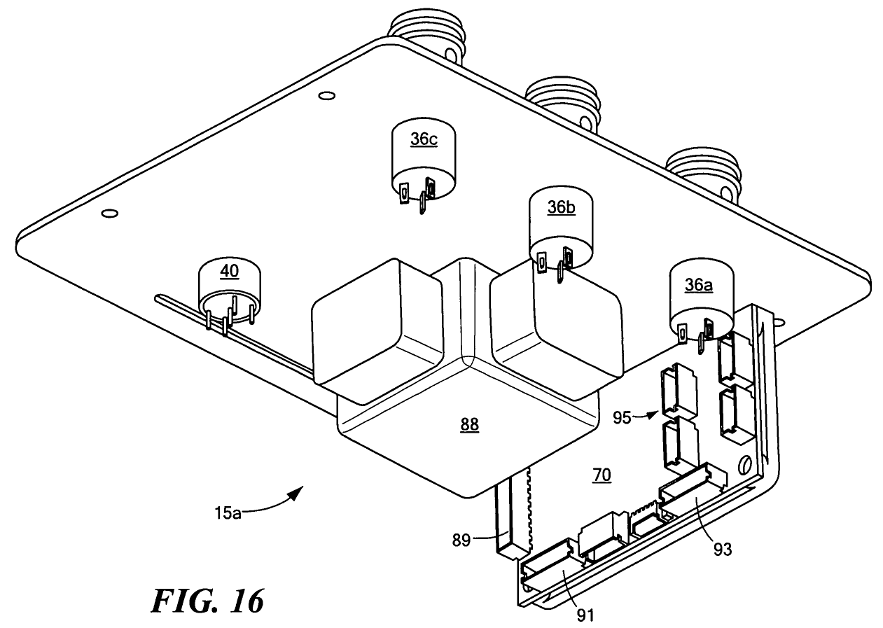

FIG. 14 shows module interface 30 in the form of a printed circuit board depending downward from the rear face of module plate 86 and supported by circuit board support plate 88. Typically, module interface circuit board 30 is configured to include connectors 89, 91, 93, and 95 as shown in FIG. 16 for wires or cables extending between the switches 36a-c, 40 and the circuit board.

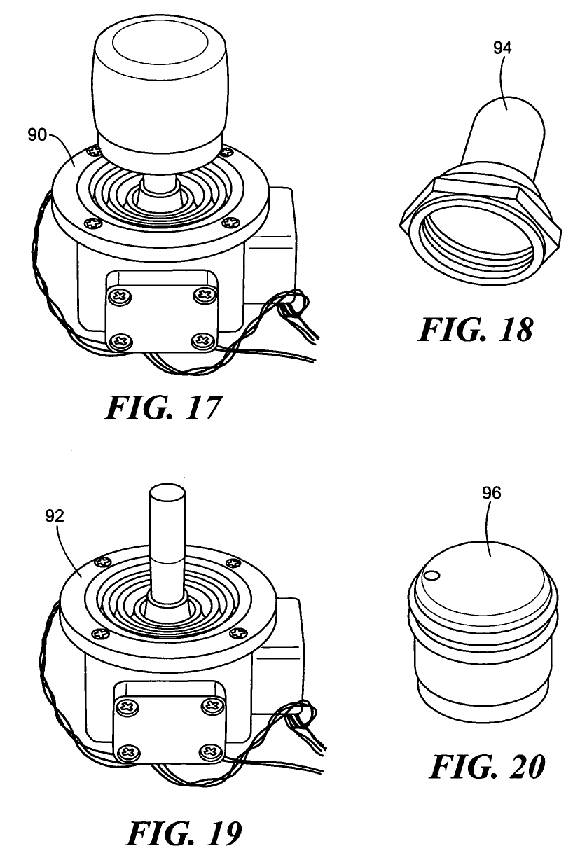

Various switches, FIGS. 17-20, may be used in connection with the control modules to control a robot. For example, three-axis, Hall-effect joysticks 90 and 92 may be used to control the functions and orientation of the robot and its cameras. Push button switch 94 may be used to control functions, such as the push to talk button 38 of FIG. 13. Dial 96 may also be used to control one of the functions of the robot, such as drive speed, turret speed, and LED intensity.

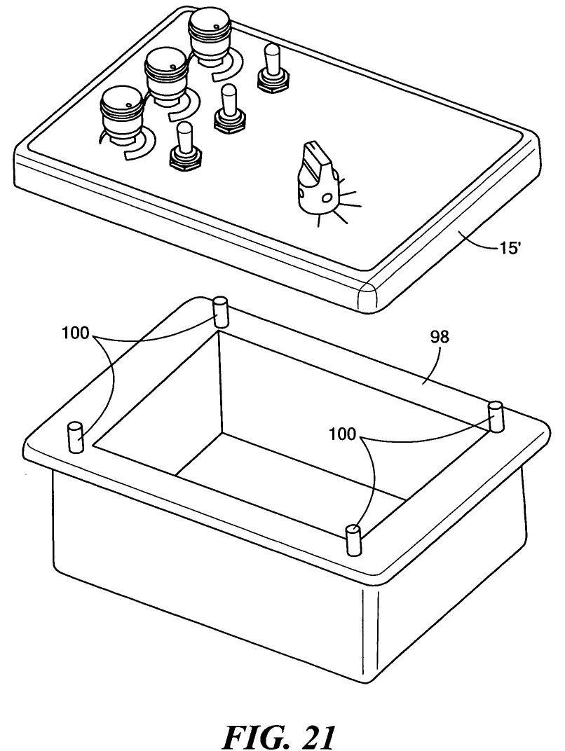

There are various methods for attaching a control module 15′, FIG. 21, to a socket 98. The control module may be sealingly engaged over a socket and then screwed in, or as shown in FIG. 21, the control module may be situated upon posts 100 that enable the control module 15′ to be attached to the socket 98.

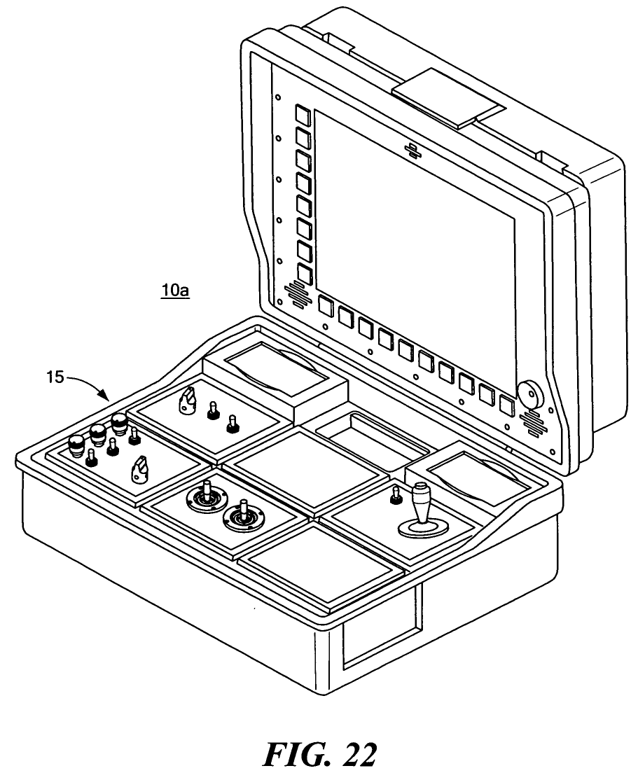

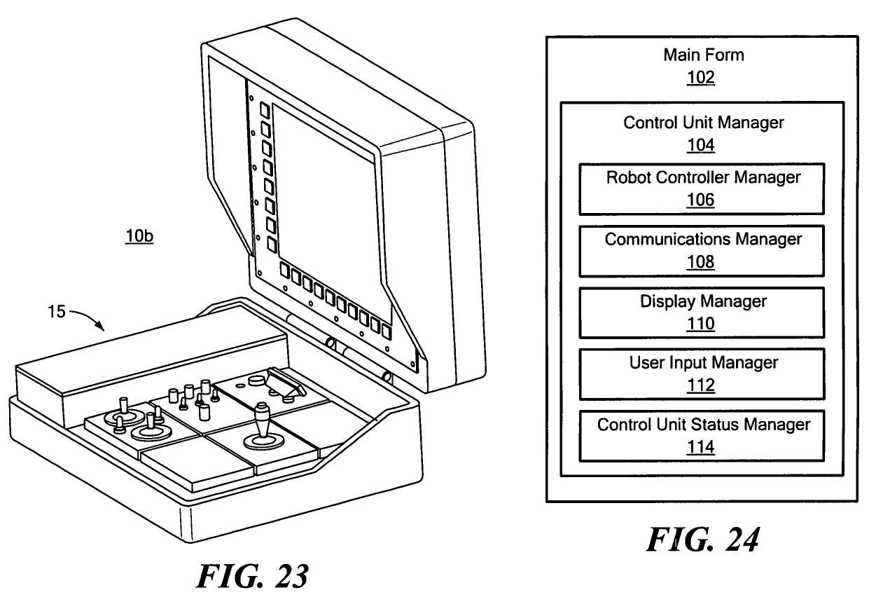

Although FIGS. 3 and 6-7 show one embodiment of the operator control unit 10, the features shown therein are not limitations of the subject invention. For example, operator control units 10a and 10a, FIGS. 22 and 23, show different arrangements of the control modules 15 and their corresponding sockets.

### Software Components of the Control Unit

There are two main software components of control unit 10, FIG. 3, which are the main form 102, FIG. 24, and the control unit manager 104. Main form 102 uses an embedded Windows XP operating system and may not implement any logic of the control unit software. Main form 102 includes three panels such as the left and bottom panels that display soft button names and states, and the main panel that displays control unit and robot information. This logic of control unit 10 is implemented in the control unit manager 104. The software of control unit 10 may be run on a processor with code executable thereon.

### Control Unit Manager

Control unit manager 104 implements the main logic of control unit 10. The software orchestrates user input via joysticks, switches and other controls, sends the corresponding control messages to the robot, and displays control unit and robot information on the display.

Various aspects of the application functionality are controlled by specific managers. A user input manager 112 is responsive to the reconfigurable user interface and interprets the function of the switches of the control modules, monitors the user interface and processes changes in the user interface. A robot controller manager 106 is responsive to the user input manager and monitors data relating to operating the robot. A robot communications manager 108 is responsive to the robot controller manager and is for communicating signals to the robot based on the activation of the module switches. A display manager 110 is for controlling the display of user information. A control unit status manager 114 is for indicating the status of the robot.

### Robot Controller Manager

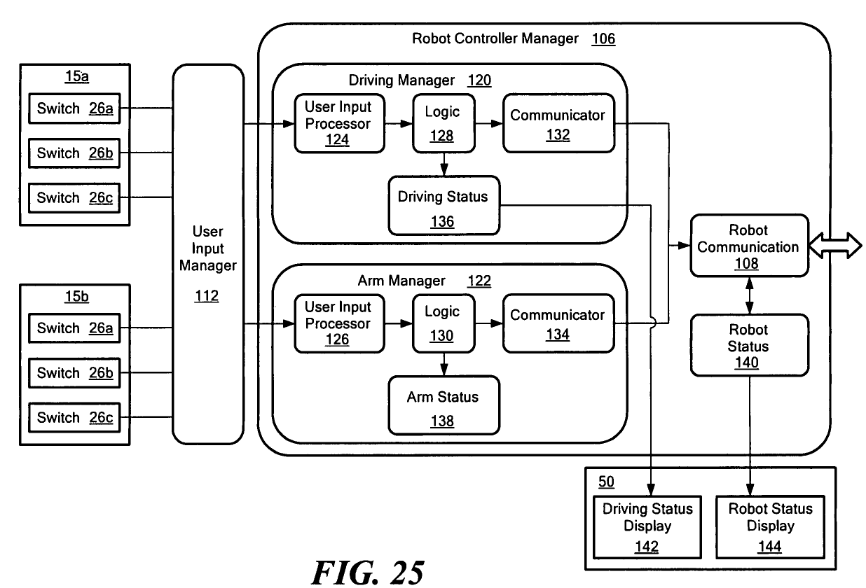

Robot controller manager 106, FIG. 25, preferably splits its functionality between several components. For example, robot controller manager 106 may include a driving manager 120 responsive to the user input manager for monitoring data relating to driving the robot, and an arm manager 122 responsive to the user input manager for monitoring data relating to operating an arm of the robot. The robot controller manager 106 may also include a fire component. Adding new functionality to control unit 10 in the future may be possible without changing any of the existing robot controller code. For example, adding a new payload would require development of a new payload component while the code in the robot controller manager may not need to be changed at all.

Each component inside the robot controller manager 106 preferably provides certain functionality. For example, driving manager 120 and arm manager 122 use logic 128 and 130, respectively, to monitor the user input manager 112, such as through its user input manager 112 described in more detail below. User input processors 124 and 126 process changes in the user interface using and the information coming from the robot's messages and updates the status. Communicators 132 and 134 inform robot communication object 108 about the need to send a command to the robot. Status providers 136, 138, and 140 provide the status of driving manager 120 and arm manager 122, respectively, to panels 142 and 144 on display 50.

In one embodiment, a single robot controller implements control of a single robot. The reconfigurability of the control unit, however, allows for multiple robot controllers so that a single control unit can control multiple robots.

### User Input Manager

The assignment of user controls to input processors or managers is done by user input manager 112. User input manager 112 is responsive to switches 26a-c of modules 15a and 15b and interprets their function. User input manager 112 also monitors the reconfigurable user interface for changes in therein such as the addition or removal of a control module from control unit 10.

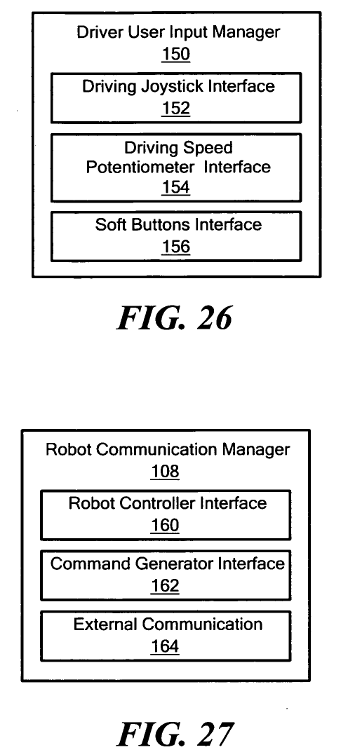

To accommodate the utilization of various user interface controls by a single component, user input manager 112 contains a collection of user interface controls. For example, driving user input manager 150, FIG. 26, monitors the driving joystick with interface 152, the driving speed knob with interface 154 and the display soft buttons with interface 156 when they are in the driving mode. The assignment of user controls to input processors or managers is done by user input manager 112.

### Communications Manager

Robot communications manager 108, FIG. 27, is responsive to robot controller manager 106 and managers communication of singles to the robot based upon activation of module switches. Depending on the command protocol used by the robot, a specific command generator class is used in robot communication manager 108. Robot communication manager 108 preferably uses references to three components to perform its work: a robot controller interface 160 to get information about the state of user interface controls, a command generator interface 162 to generate commands, and external communication module 164 that manages communication with the robot to send, for example, connect/disconnect or send/receive messages.

### Status Manager

States manager 114, FIG. 24, manages the indication of the status of the robot. This will allow developing displays that are independent of the user interface, the logic and the communication objects contained in the control unit. Status manager 114 may contain an array of status providers. These status providers may display status of control unit components and/or switches on the screen. Inside control unit 10, each component 120, 122, etc., may contain its own status provider such as status providers 136 and 138, respectively.

### Display Manager

Display manager 40 controls the display of information on monitor 18. Display manager 110 includes the soft buttons manager which manages soft buttons names and states, and one or more robot panel objects for managing a display for each robot. The robot panel object controls a number of specific displays showing the control unit and robot status.

Display manager 110 can assign buttons or dials on monitor 18 to a specific robot controller. Display manager 110 can also assign or provide a portion of the screen to a specific robot controller.

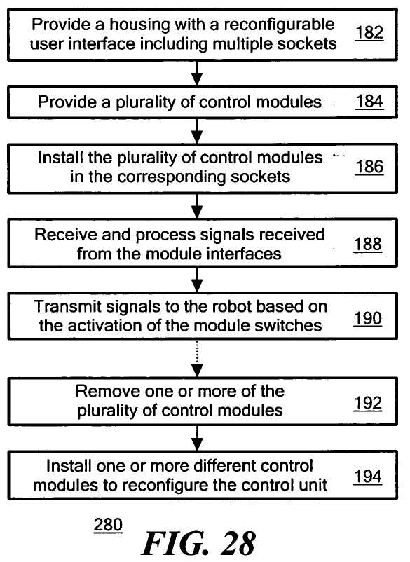

A flowchart 180, FIG. 28, for a method of providing a mobile robot operator control unit to remotely control a robot begins at step 182 with providing a housing with a reconfigurable user interface including multiple sockets. A plurality of control modules are provided at step 184 in which each control module includes one or more switches, and a module interface connected to the one or more switches. At step 186, each of the plurality of control modules are installed in the corresponding sockets to provide an initial configuration of the control mechanisms of the control unit. At step 188, signals are received and processed from the module interfaces. At step 190, signals are transmitted to the robot based on the activation of the module switches.

In one embodiment, the method may further include step 192 which includes removing one or more of the plurality of control modules from their corresponding sockets, and step 194 which includes installing one or more different control modules to reconfigure the initial configuration of the control mechanisms of the control unit.

Although specific features of the invention are shown in some drawings and not in others, this is for convenience only as each feature may be combined with any or all of the other features in accordance with the invention. The words “including”, “comprising”, “having”, and “with” as used herein are to be interpreted broadly and comprehensively and are not limited to any physical interconnection. Moreover, any embodiments disclosed in the subject application are not to be taken as the only possible embodiments.

In addition, any amendment presented during the prosecution of the patent application for this patent is not a disclaimer of any claim element presented in the application as filed: those skilled in the art cannot reasonably be expected to draft a claim that would literally encompass all possible equivalents, many equivalents will be unforeseeable at the time of the amendment and are beyond a fair interpretation of what is to be surrendered (if anything), the rationale underlying the amendment may bear no more than a tangential relation to many equivalents, and/or there are many other reasons the applicants can not be expected to describe certain insubstantial substitutes for any claim element amended.

Other embodiments will occur to those skilled in the art and are within the following claims.

What is claimed is:

1. A mobile operator control unit for remotely controlling a robot, the control unit comprising:
a housing with a reconfigurable user interface including multiple sockets;
a plurality of control modules each removably received in a socket and including:
one or more switches, and
a module interface connected to the one or more switches;
a baseboard processing unit electrically connected to each module interface for receiving and processing signals received from the module interfaces; and
a transmitter responsive to the baseboard processing unit for transmitting signals to the robot based on the activation of the module switches.

2. The operator control unit of claim 1 in which each module interface is configured to convert signals received by the switches to a common format.

3. The operator control unit of claim 2 in which said format is compatible with a USB connection between each module interface and the baseboard processing unit.

4. The operator control unit of claim 1 in which the switches include dials, joysticks, buttons, and/or selection switches.

5. The operator control unit of claim 1 in which each control module includes:
a plate housing the switches,
a circuit board support depending downward from a rear face of the plate into a socket, and
the module interface is configured as a circuit board supported by the support and including connectors for wires extending between the switches and the circuit board.

6. The operator control unit of claim 5 in which said plate is removably and sealingly engaged over a socket.

7. The operator control unit of claim 1 in which the housing further includes a monitor.

8. The operator control unit of claim 1 in which the transmitter is housed in a robot communications pack removably attached to the housing.

9. The operator control unit of claim 1 further including a lid hinged to a base and the panel is the top surface of the base.

10. The operator control unit of claim 9 in which the lid includes a monitor.

11. The operator control unit of claim 10 in which the transmitter is housed in a robot communications pack removably attached to the back of the lid.

12. A mobile operator control unit for remotely controlling a robot, the control unit comprising:
a housing with a reconfigurable user interface including multiple sockets, each socket configured to removably receive one of a plurality of control modules for configuring the control mechanisms of the control unit;
a common interface connected to each socket;
a baseboard processing unit electrically connected to the socket interface for receiving and processing signals received from the module interfaces; and
a transmitter responsive to the baseboard processing unit for transmitting signals to one or more robots based on the activation of the module switches.

13. The operator control unit of claim 12 further including the plurality of control modules in which each control module includes one or more switches and a module interface connectable to the common interface.

14. The operator control unit of claim 12 in which the housing further includes a monitor.

15. The operator control unit of claim 12 further including a lid hinged to a base and the panel is the top surface of the base.

16. The operator control unit of claim 15 in which the lid includes a monitor.

17. A mobile operator control unit for remotely controlling a robot, the control unit comprising:
a housing with a reconfigurable user interface including a plurality of control modules each removably received in the control unit and including one or more switches;
a processor having code executable thereon, the code including:
a user input manager responsive to the switches for interpreting the function of the switches and monitoring the user interface for changes in the user interface;
a robot controller manager responsive to the user input manager for monitoring data relating to operating the robot;
a robot communications manager responsive to the robot controller manager for communicating signals to the robot based on the activation of the module switches;
a display manager for controlling the display of information; and
a status manager for indicating the status of the robot.

18. The operator control unit of claim 17 in which the robot controller manager includes:
a driving manager responsive to the user input manager for monitoring data relating to driving the robot; and
an arm manager responsive to the user input manager for monitoring data relating to operating an arm of the robot.

19. A method for providing a mobile robot operator control unit to remotely control a robot, the method comprising the steps of:
providing a housing with a reconfigurable user interface including multiple sockets;
providing a plurality of control modules each including: one or more switches and a module interface connected to the one or more switches;
installing the plurality of control modules in the corresponding sockets to provide an initial configuration of the control mechanisms of the control unit;
receiving and processing signals received from the module interfaces; and
transmitting signals to the robot based on the activation of the module switches.

20. The method of claim 19, further including the steps of:
removing one or more of the plurality of control modules from their corresponding sockets; and
installing one or more different control modules to reconfigure the initial configuration of the control mechanisms of the control unit.
